(19) United States
(12) Patent Application Publication
(10) Pub. No.: US 2009/0034187 A1
(43) Pub. Date: Feb. 5, 2009

(54) PRESSURE-BASED FAN SPEED ADJUSTMENT

(76) Inventors: Henry C. COLES, Saratoga, CA (US); Vance Murakami, Los Gatos, CA (US); Wesley H. Stelter, San Bruno, CA (US); Richard A. Bargerhuff, Houston, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/831,677

(22) Filed: Jul. 31, 2007

(51) Int. Cl. H05K 7/20

(52) U.S. Cl. 361/687; 361/690; 361/695

(57) ABSTRACT

A system comprising a container adapted to house an electronic device. The system also comprises a fan adapted to transfer air between different portions of the container and pressure sensing logic adapted to determine a difference between air pressures at the different portions. The system further comprises control logic adapted to adjust a speed of the fan in accordance with the difference.

### BACKGROUND

Many electronic devices, such as personal computers and servers, house internal fans that provide airflow used to expel heat generated during operation. Proper airflow (e.g., fan operation) often requires some predetermined difference in air pressure between one side of the electronic device (i.e., a front side of the fan) and another side of the electronic device (i.e., a rear side of the fan). When such electronic devices are deprived of suitable differences in air pressure, the required airflow may be compromised and the electronic device containing the fan may be susceptible to an unwanted shutdown, reduced reliability or damage from overheating.

Such electronic devices may be stored in equipment containers (e.g., server racks). Many equipment containers contain cooling systems that are used to remove heat generated by electronic devices housed therein. Specifically, these equipment containers may be sealed (i.e., virtually airtight for the purpose of cooling) and may be cooled using fans and air-to-liquid heat exchangers. However, such sealed containers often cause unsuitable air pressure differences to develop between different sides of the electronic devices housed inside, thereby compromising fan operation inside the electronic devices and resulting in unwanted shutdown, reduced reliability or damage to the electronic devices.

### BRIEF DESCRIPTION OF THE DRAWINGS

For a detailed description of exemplary embodiments of the invention, reference will now be made to the accompanying drawings in which:

FIG. 1 shows a 3-D view of an illustrative equipment container implementing the techniques disclosed herein in accordance with various embodiments;

FIG. 2 shows a detailed view of the equipment container of FIG. 1, in accordance with various embodiments;

FIG. 3 shows an illustrative top-down view of the equipment container of FIG. 1 in block diagram form and in accordance with various embodiments;

FIG. 4 shows another 3-D view of the equipment container of FIG. 1, in accordance with various embodiments;

FIG. 5 shows yet another 3-D view of the equipment container of FIG. 1, in accordance with various embodiments;

FIG. 6a shows a flow diagram of an illustrative method implemented in accordance with various embodiments; and

FIG. 6b shows a flow diagram of another illustrative method implemented in accordance with various embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

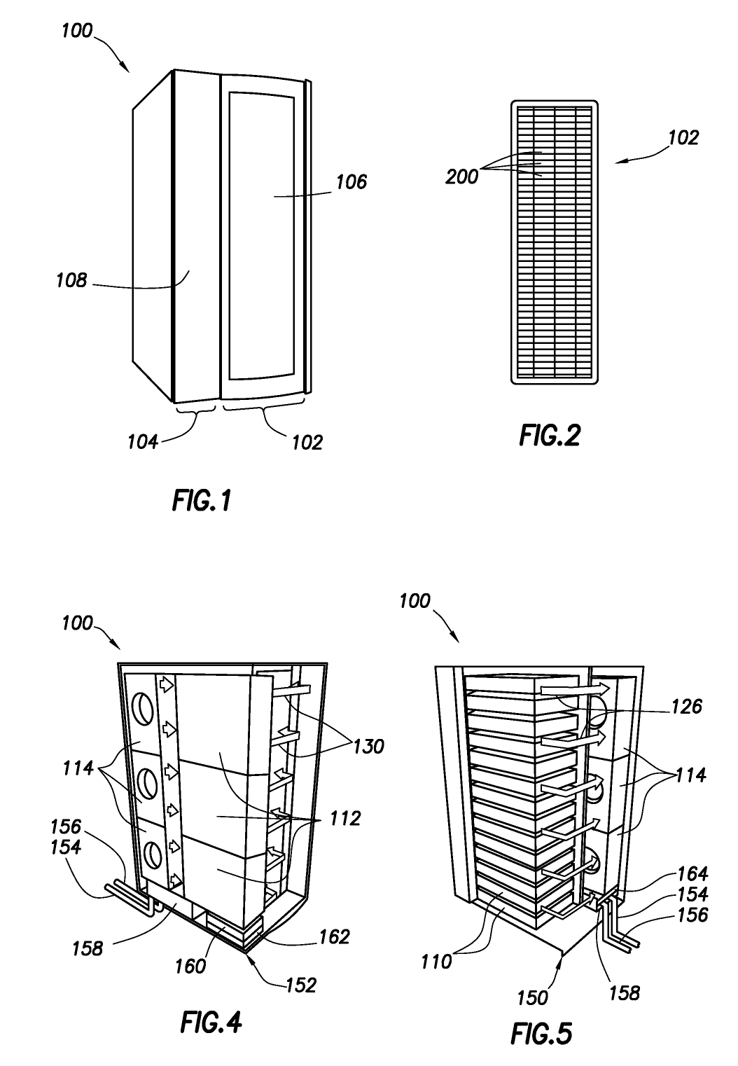

Disclosed herein are various techniques by which air pressures within equipment containers may be regulated to prevent heat-related damage to electronic devices housed within the equipment containers. FIG. 1 shows a 3-D view of an illustrative equipment container 100 implementing at least some of the techniques disclosed herein. The equipment container 100 may be of any suitable size, color, shape, etc. The container 100 comprises an electronic device compartment 102 and a cooling system compartment 104. The electronic device compartment 102 is primarily adapted to house one or more electronic devices, such as servers, personal computers, power supplies, etc. The cooling system compartment 104 houses various types of equipment used to cool the electronic devices, such as fans, heat exchangers, etc. The electronic device compartment 102 may be accessed via a door 106 and the cooling system compartment 104 may be accessed via a door 108. In at least some embodiments, the equipment container 100 comprises a sealed (i.e., airtight or substantially airtight) container designed for refrigerated cooling of electronic devices stored in the container 100.

FIG. 2 shows a detailed view of at least a portion of the electronic device compartment 102. As shown, the electronic device compartment 102 comprises a plurality of electronic device containers 200. The containers 200 may house any suitable type of electronic device, such as servers. The scope of this disclosure is not limited to any particular type of container 200 or number of containers 200. Further, the scope of this disclosure includes embodiments in which at least some of the containers 200 in a single equipment container 100 are of different types.

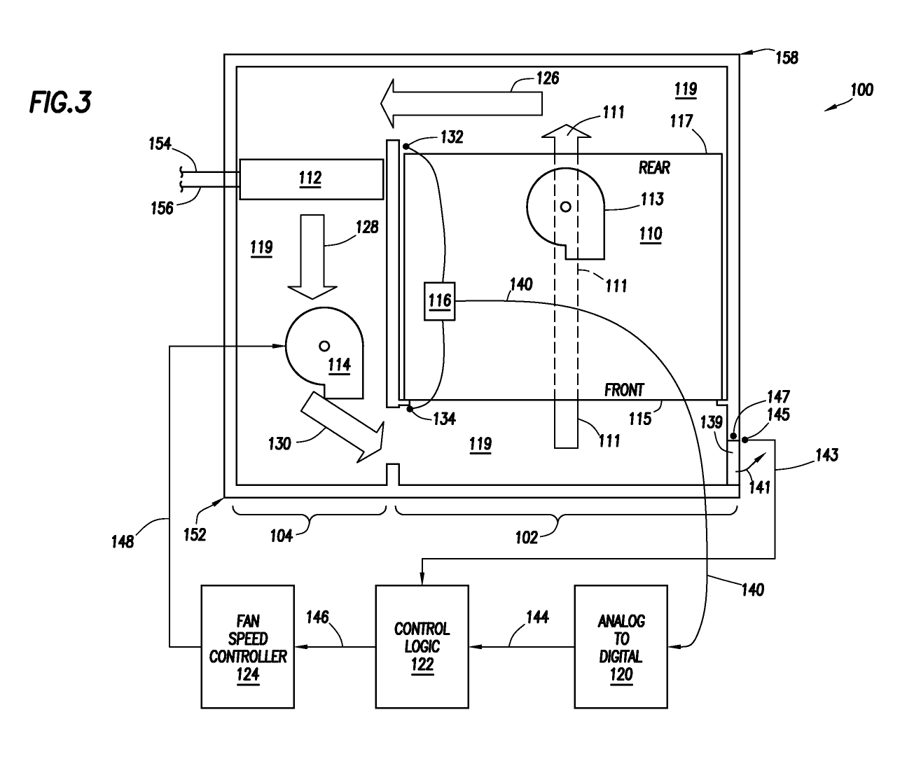

FIG. 3 shows a detailed, top-down view of the equipment container 100. As shown, the container 100 comprises an electronic device 110 (e.g., a server), a heat exchanger (or any suitable cooling element) 112, a fan 114, a pressure monitor 116 having pressure detectors 132 and 134, an analog-to-digital (A/D) converter 120, a control logic 122 and a fan speed controller 124. In some embodiments, the container 100 also comprises a pressure-sensitive door 139, described below. Although the A/D converter 120, control logic 122 and fan speed controller 124 are shown as being located outside the equipment container 100, in at least some embodiments, the A/D CONVERTER 120, control logic 122 and fan speed controller 124 may be housed in any suitable location within the equipment container 100.

The electronic device 110 may be housed within one of the plurality of containers 200 shown in FIG. 2. The electronic device 110 comprises a fan 113 which draws cool air in at the front side 115 of the server 110 and expels warm air at the rear side 117 of the server 110, as indicated by arrow 111. Warm air expelled by the electronic device 110 into the duct 119, as indicated by arrow 126, is cooled by the heat exchanger 112. The heat exchanger 112 receives cool liquid (e.g., water) via liquid inlet 154 and outputs warm liquid via liquid outlet 156. The heat exchanger 112 transfers heat from the warm air 126 to the cool liquid, thereby cooling the air and heating the liquid. The heated liquid is carried away via outlet 156. The cooled air is output from the heat exchanger 112, as indicated by arrow 128. The cool air 128 is then pushed through duct 119 by fan 114, as indicated by arrow 130, to the front side 115 of the server 110, thereby completing the airflow cycle of the container 100. The scope of this disclosure is not limited to the use of a heat exchanger. Any suitable cooling element that is able to cool the air within the duct 119 may be used.

In accordance with various embodiments, the equipment container 100 comprises one or more pressure monitors. As shown in the illustrative embodiment of FIG. 3, the container 100 may comprise a pressure monitor 116. The pressure monitor 116 couples to pressure detectors 132 and 134. The pressure detector 132 is located at or near the rear side 117 of the equipment container 100. The pressure detector 134 is located at or near the front side 115 of the equipment container 100. Although the scope of this disclosure is not limited to any particular location of the detectors 132 and 134, in at least some embodiments, the detectors 132 and 134 are located on opposite sides of the fan 113.

The detectors 132 and 134 detect the air pressure of their respective environments (i.e., locations within the conduit 119), convert the detected air pressures into electrical signals, and transfer the signals to the pressure monitor 116. In turn, the pressure monitor 116 determines a difference between the air pressures detected by the detectors 132 and 134 and transfers a signal encoding this difference to the (A/D) converter 120. The A/D converter 120 converts signals received from the pressure monitor 116 to digital signals. These digital signals are provided to control logic 122 via connection 144. Based on the difference in pressure detected between the detectors 132 and 134, and further based on a predetermined target pressure difference stored in the controller 122, the control logic 122 may adjust, or cause the adjustment of, the speed of the fan 114. For example, if the target pressure (e.g., the pressure at detector 134 minus the pressure at detector 132) difference is greater than the pressure difference detected by the monitor 116 (i.e., using the detectors 132 and 134), the control logic 122 may decrease the speed of fan 114, thereby decreasing the air pressure near the front side 115 of the device 110 and increasing the air pressure near the rear side 117 of the device 110. In this way, the difference in air pressures is moved closer to the target pressure difference stored in the control logic 122. Alternatively, if the target pressure difference is less than the pressure difference detected by the monitor 116, the control logic 122 may increase the fan speed, thereby increasing the air pressure near the front side 115 of the device 110 and decreasing the air pressure near the rear side 117 of the device 110.

The control logic 122 may adjust the speed of the fan 114 by providing adjustment signals to the fan controller 124 (via connection 146) which, in turn, increases or decreases the speed of the fan 114 (via connection 148) in accordance with the adjustment signals. Although FIG. 3 shows the equipment container 100 comprising only one monitor 116 with corresponding detectors 132 and 134, in at least some embodiments, the container 100 may comprise multiple pressure monitors, each monitor with multiple pressure detectors located in areas of the duct 119 suitable for determining air pressures within the duct 119. In at least some cases, the control logic 122 may factor in (e.g., average) all such signals together to determine what the fan speed should be.

In some embodiments, the equipment container 100 comprises a pressure-sensitive door 139. Unlike the doors 106 and 108, the door 139 is used to monitor air pressure within the duct 119 and to adjust the speed of the fan 114. The door 139 may be of any size, shape, etc. as long as its physical characteristics render the door 139 usable for the purposes described below. The door 139 couples to a hinge 147. As indicated by arrow 141, the door 139 is capable of opening outward (i.e., away from the duct 119). The door 139 is described as being “pressure-sensitive” because the door 139 opens when air pressure within the duct, and especially near the front side 115 of the electronic device 110, reaches some predetermined threshold. The predetermined threshold air pressure that causes the door 139 to open depends on the physical characteristics of the door 139, the tightness with which the door 139 couples to the hinge 147, etc. Accordingly, the door 139 and the hinge 147 may be designed such that the door 139 opens when a desired air pressure forms against the door 139 inside the duct 119. In some embodiments, the hinge 147 may comprise a spring and, thus, the threshold air pressure may be associated with the physical characteristics (e.g., weight) of the door 139 as well as the spring constant of the spring.

When the threshold pressure applied against the door 139 from within the duct 119 reaches the predetermined air pressure threshold, the door 139 opens and an alert apparatus 145 generates and transfers an alert signal to the control logic 122 via connection 143. The alert apparatus 145 may comprise any suitable mechanism, such as a switch, which generates an alert signal when the door 139 opens. This alert signal alerts the control logic 122 that the air pressure against the door 139 within the duct 119 has exceeded the predetermined air pressure threshold and, in turn, the control logic 122 may cause the fan speed controller 124 to adjust the air pressure within the duct 119 by adjusting the speed of the fan 114. For example, if a target air pressure near the front side 115 of the electronic device 110 is 0.5 pounds per square inch (psi), the pressure threshold may be set at 0.6 psi. Accordingly, when the air pressure pressing against the door 139 from within the duct 119 reaches 0.6 psi, the door 139 opens. The door may be of dimensions such that, when opened, air pressure within the duct 119 is not substantially affected. Stated otherwise, the size of the orifice created by the opening of the door is small enough so that the total airflow is not affected. Opening of the door causes an alert signal to be sent from the alert apparatus 145 to the control logic 122. In turn, the control logic 122 may cause the fan speed controller 124 to reduce the speed of the fan 114 just until the door 139 closes (i.e., until the alert apparatus 145 stops sending an alert signal or, alternatively, until the alert apparatus 145 sends a “stop” signal), thereby causing the air pressure near the front side 115 to drop to the target air pressure of 0.5 psi.

In some embodiments, the door 139 is included in the equipment container 100 with the pressure monitor 116 and pressure detectors 132 and 134. However, in other embodiments, the door 139 is included in the container 100 and the pressure monitor 116 and detectors 132, 134 are not included in the container 100. In yet other embodiments, the pressure monitor 116 and detectors 132, 134 are included in the container 100 but the door 139 is not included in the container 100.

FIG. 3 illustrates the use of a single heat exchanger 112, a single fan 114 and a single electronic device 110 in the container 100. In other embodiments, a different number of such equipment can be provided. For example, a single heat exchanger 112 may be used to cool airflow provided to multiple electronic devices. Similarly, in some embodiments, a single fan 114 may be used to provide airflow to multiple electronics devices. Likewise, multiple heat exchangers 112 and/or fans 114 may be used to service a single electronic device. All such variations and combinations are included within the scope of this disclosure.

FIG. 4 shows a 3-D front/side view (along arrow 152 of FIG. 3) of some of the contents of the equipment container 100. As shown, the container 100 comprises 3 fans 114 and 3 heat exchangers 112. In at least some embodiments (e.g., the embodiment of FIG. 3), the fans 114 may be located where the heat exchangers 112 are shown to be, and the heat exchangers 112 may be located where the fans 114 are shown to be. The container 100 receives cool liquid via liquid inlet 154 and outputs warm liquid via liquid outlet 156. The inlet 154 and outlet 156 couple to a liquid group 158. The liquid group 158 is controlled by a liquid group controller 162 and provides cool liquid to and removes warm liquid from the heat exchangers 112. The container 100 also comprises an AC transfer unit 160, which enables the use of multiple, independent AC sources to operate the system. For example, one source may comprise a universal power supply (UPS) and another source may comprise a standard wall plug. If one of the AC sources goes down, the other AC source may be used. Arrows 130 indicate that air output from the heat exchangers 112 (or, if the positions of the fans and heat exchangers are switched, from the fans 114) is provided to the front sides of the electronic devices stored in the container 100.

FIG. 5 shows a 3-D rear/side view (along arrow 150 of FIG. 3) of some of the contents of the equipment container 100. As shown, the container 100 comprises the 3 fans 114. The fans 114 (or, in embodiments where the fans and heat exchangers are switched, the heat exchangers 112) receive warm air from the plurality of electronic devices 110, as indicated by arrows 126. The container 100 comprises a patch panel 164 comprising connectors through which the container 100 receives power and network communication capabilities (e.g., Ethernet connectors). As previously described, the liquid inlet 154 provides cool liquid to the liquid group 158 and the liquid outlet 156 removes warm liquid from the liquid group 158.

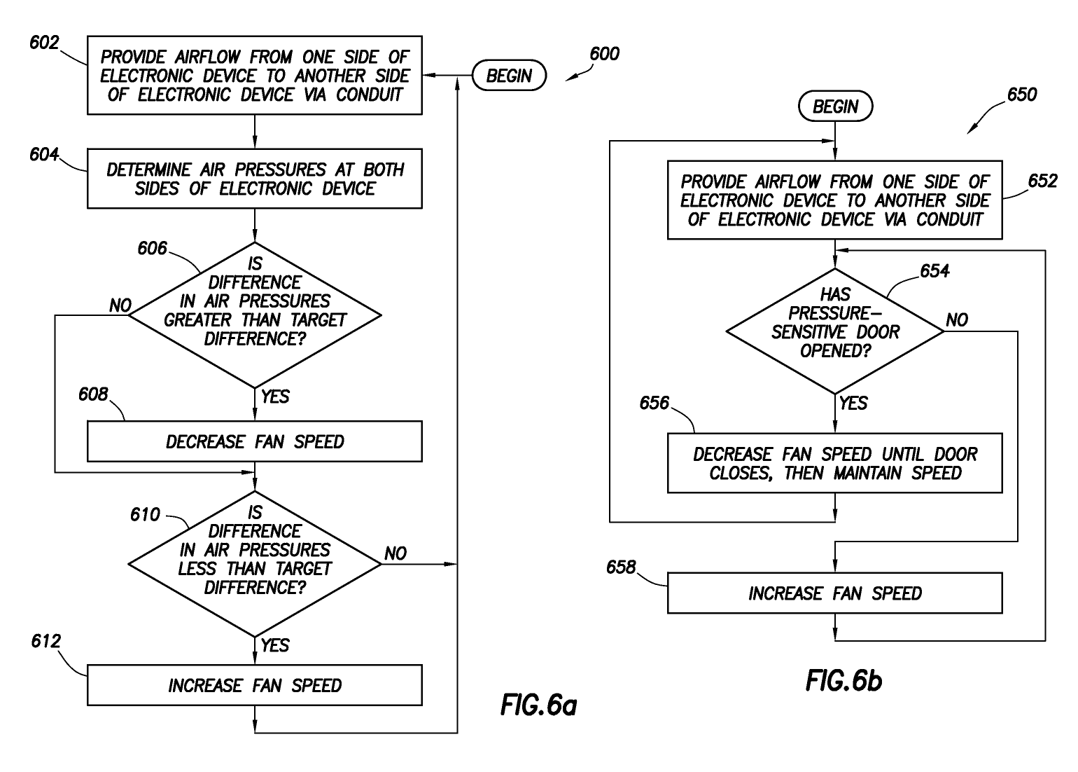

FIG. 6a shows a flow diagram of an illustrative method 600 implemented in accordance with various embodiments. The method 600 begins by providing airflow from one side of the electronic device to another side of the electronic device via the duct (block 602). The method 600 then comprises determining air pressures at both sides of the electronic device (block 604). The method 600 also comprises determining whether the difference in air pressures is greater than a target difference (block 606). If so, the method 600 comprises decreasing the fan speed (block 608). Regardless, the method 600 further comprises determining whether the difference in air pressures is less than the target difference (block 610). If so, the method 600 comprises increasing the fan speed (block 612). Control of the method 600 then is provided to block 602. The steps of method 600 may be performed in any suitable, desired order.

FIG. 6b shows another illustrative method 650 implemented in accordance with various embodiments. The method 650 begins by providing airflow from one side of an electronic device to another side of the electronic device via a duct (block 652). The method 650 then comprises determining whether a pressure-sensitive door has opened (block 654). If so, the method 650 comprises decreasing the fan speed until the door closes and then maintaining that fan speed (block 656) and returning control of the method 650 to block 652. Otherwise, the method 650 comprises increasing the fan speed (block 658) and returning control of the method 650 to block 654. The steps of method 650 may be performed in any suitable, desired order.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a container adapted to house an electronic device;
a fan adapted to transfer air between different portions of the container;
pressure sensing logic adapted to determine a difference between air pressures at said different portions; and
control logic adapted to adjust a speed of the fan in accordance with said difference.

2. The system of claim 1, wherein the system comprises a duct adapted to transfer said air between said different portions of the container, and wherein the fan is positioned inside the duct such that a cooling element cools the air before the air is provided to the fan.

3. The system of claim 1, wherein the system further comprises a pressure-sensitive door which opens when an air pressure associated with the system exceeds a predetermined threshold, and wherein, if said door opens, a signal is sent from the door to the control logic and, in turn, the control logic adjusts said speed of the fan.

4. The system of claim 3, wherein the control logic decreases said speed of the fan until the door closes and then the control logic stops decreasing said speed of the fan.

5. The system of claim 1, wherein the system comprises a server rack sealed to prevent the escape of at least some air.

6. The system of claim 1, wherein the control logic comprises a predetermined, target difference, and wherein the control logic adjusts the speed of the fan until the difference meets said predetermined, target difference.

7. A method, comprising:
providing a container adapted to house an electronic device;
determining a difference between air pressures associated with different parts of said container; and
adjusting a speed of a fan in accordance with said difference such that said difference meets a predetermined target difference.

8. The method of claim 7, wherein providing said container comprises providing a container which is at least partially sealed to prevent the escape of air from inside the container.

9. The method of claim 7 further comprising cooling said gas prior to providing said gas to the fan.

10. The method of claim 7, wherein increasing the speed of the fan causes a gas pressure at said front side to increase and another gas pressure at said rear side to decrease.

11. The method of claim 7, wherein decreasing the speed of the fan causes a gas pressure at said front side to decrease and another gas pressure at said rear side to increase.

12. The method of claim 7 further comprising providing a door that opens when a gas pressure at said front side meets or exceeds a predetermined threshold.

13. The method of claim 12 further comprising decreasing said speed of the fan if said door opens.

14. The method of claim 7, wherein said target difference is such that a gas pressure at said front side is greater than another gas pressure at said rear side.

15. A system, comprising:
an electronic device having an input and an output;
means for moving gas from said output to said input;
means for determining a difference between gas pressures associated with said input and said output; and
means for adjusting a speed of the means for moving gas in accordance with said difference such that said difference meets a target difference.

16. The system of claim 15, wherein the system comprises a sealed equipment container and said electronic device comprises a personal computer or a server.

17. The system of claim 15 further comprising means for carrying gas from said output to said input, wherein the means for carrying comprises the means for moving and means for cooling the gas, and wherein said means for moving is positioned closer to the input than to the output and the means for cooling is positioned closer to the output than to the input.

18. The system of claim 15 further comprising a mechanism adapted to move when a gas pressure at said input meets or exceeds a predetermined threshold.

19. The system of claim 18, wherein the means for adjusting adjusts said means for moving gas if the means for adjusting detects that said mechanism has moved.

20. The system of claim 15, wherein said target difference is such that a gas pressure at said input is greater than another gas pressure at said output.
